(19) United States
(12) Patent Application Publication
(10) Pub. No.: US 2007/0295958 A1
(43) Pub. Date: Dec. 27, 2007

(54) Semiconductor structure having a low hot-carrier effect characteristic

(75) Inventors: Chiung-Wei Lin, Taipei City (TW); Chien-Feng Lee, Taipei City (TW); Yi-Liang Chen, Taipei City (TW)

Correspondence Address: BACON & THOMAS, PLLC, 625 SLATERS LANE, FOURTH FLOOR, ALEXANDRIA, VA, 22314, US

(73) Assignee: Tatung Company, Taipei City (TW)

(21) Appl. No.: 11/656,988

(22) Filed: Jan. 24, 2007

(30) Foreign Application Priority Data
Jun. 26, 2006 (TW) 095122927

(51) Int. Cl. H01L 29/08

(52) U.S. Cl. 257/40

(57) ABSTRACT

The present invention relates to a semiconductor structure having a low hot-carrier effect characteristic, and, more particularly, to a semiconductor structure capable of reducing the detrimental influence of the happening of the hot-carrier effect on the performance of the transistor having the semiconductor structure, even after the transistor has been operated under an operation environment with high channel electric field. The semiconductor structure comprises: a substrate; a metal layer formed on parts of the surface of the substrate; an insulation layer formed on the surface of the substrate and covering the surface of the metal layer; a first semiconductor layer covering parts of the surface of the insulation layer; and a second semiconductor layer covering parts of the surface of the first semiconductor layer. Besides, the second resistance of the second semiconductor layer is larger than the first resistance of the first semiconductor layer.

### BACKGROUND OF THE INVENTION

1. Field of the Invention

The present invention relates to a semiconductor structure having a low hot-carrier effect characteristic, and, more particularly, to a semiconductor structure capable of reducing the detrimental influence of the hot-carrier effect on the performance of the transistor having the semiconductor structure, even after the transistor has been operated under an operation environment with high channel electric field.

2. Description of Related Art

In recent years, since the size of a semiconductor structure has become minimized, the hot-carrier effect has happened more frequently as the semiconductor is being operated. When the voltage drop between the two terminals of the channel layer of the transistor is so large that the charge carriers traveling in the-channel layer inject into the gate electrode insulation layer and/or the interface between the gate electrode insulation layer and the channel layer, which results in the deterioration of the performance of the transistor, this is the so-called the happening of the hot-carrier effect. In general, the hot-carrier effect only happens to a transistor having a small-size channel layer. But if the working current of the transistor is required to be larger than a certain level in certain application environment, such as the transistors of the driver ICs of an OLED display device, the hot-carrier effect may also happen during the operation of the transistors with their channel layer of normal size.

In order to minimize the detrimental influence of the happening of the hot-carrier effect on the performance of the transistor, a transistor having the lightly doped drain electrode structure (LDD structure) is proposed, in order to limit the kinetic energies of the charge carriers traveling in the channel layer of the transistor. A transistor having the lightly doped drain electrode structure is shown in FIG. 1A, wherein the transistor 1 comprises a glass substrate 11, a gate electrode insulation layer 13, a channel layer 14, a lightly doped drain electrode region 15, a heavily doped drain electrode region 16, a gate electrode layer 17 and a source electrode metal layer (not shown in the figure). By doping the lightly doped drain electrode region 15 located between the channel layer 14 and the heavily doped drain electrode region 16, a large portion of the voltage drop between the two terminals of the channel layer 14 is designated to the lightly doped drain electrode region 15 having large resistance, thus the voltage drop between the heavily doped drain electrode region 16 and the source electrode metal layer is lowered. Therefore, the energies of the charge carriers traveling in the channel layer 14 are limited, and the probability of the hot-carrier effect in the transistor having the lightly doped drain electrode structure is minimized.

However this is not the complete factual situation because even though the doping concentration of the lightly doped drain electrode region 15 is lower than the doping concentration of the heavily doped drain electrode region 16, the doping concentration of the lightly doped drain electrode region 15 is still far larger than the doping concentration of the channel layer 14. Thus, the decrease of the “lateral channel voltage”, i.e. the voltage drop between the two terminals of the lightly doped drain electrode region 15, is limited. As a result, the hot-carrier effect may still happen in the transistor having the lightly doped drain electrode structure of the prior art, after the transistor has been operated for a long time. Besides, as described in a paper published in 1991, (Tomohisa Mizuno, Shizuo Sawada, Yoshikazu Saitoh, and Takeshi Tanaka, IEEE TRANSACTION ON ELECTRON DEVICES, VOL. 38, NO. 3, MARCH 1991), and the schematic diagram showing the variation of the on-current regarding the operation time of the transistor having the lightly doped drain electrode structure of the prior art shown in FIG. 1B, the on-current of the transistor having the lightly doped drain electrode structure of the prior art is lower than 98% of its initial value, after the transistor has been operated in an environment with Vgs=3 V, Vds=6 V for 2000 seconds. The decrease of the on-current of the transistor indicates the fact that the performance thereof has been badly influenced by the happening of the hot-carrier effect.

With reference to FIG. 1A again, since the lightly doped drain electrode region 15 and the doping concentration of the channel layer 14 are arranged in a horizontal direction and do not overlap with each other, the transistor having the lightly doped drain electrode structure of the prior art must cover a larger area of the substrate surface. Moreover, since a lot of masks and expensive manufacturing processes, such as the ion implantation process, are also required in the manufacturing process, the manufacturing cost of the transistor having the lightly doped drain electrode structure of the prior art can not be lowered and the yield of the manufacturing process can not be increased, either.

Therefore, it is desirable to provide a transistor having a low hot-carrier effect characteristic, which not only can minimize the detrimental influence of the hot-carrier effect on the performance of the transistor, but also have a simpler manufacturing process, for the application having a high current environment, such as the driver ICs of an OLED display device.

### SUMMARY OF THE INVENTION

The semiconductor structure having a low hot-carrier effect characteristic of the present invention comprises: a substrate; a metal layer formed on at least part of the surface of the substrate; an insulation layer formed on at least part of the surface of the substrate and covering the surface of the metal layer; a first semiconductor layer having a first resistance and covering at least part of the surface of the insulation layer; and a second semiconductor layer having a second resistance and covering at least part of the surface of the first semiconductor layer; wherein the second resistance of the second semiconductor layer is larger than the first resistance of the first semiconductor layer.

The transistor having a low hot-carrier effect characteristic of the present invention comprises: a substrate; a gate electrode metal layer formed on at least part of the surface of the substrate; an insulation layer formed on at least part of the surface of the substrate and covering the surface of the gate electrode metal layer; a first semiconductor layer having a first resistance and covering at least part of the surface of the insulation layer; a second semiconductor layer having a second resistance and covering at least part of the surface of the first semiconductor layer; a heavily doped semiconductor layer having a first upper surface and a second upper surface and covering at least part of the surface of the second semiconductor layer; a source electrode metal layer formed on the first upper surface of the heavily doped semiconductor layer; and a drain electrode metal layer formed on the second upper surface of the heavily doped semiconductor layer; wherein the second resistance of the second semiconductor layer is larger than the first resistance of the first semiconductor layer.

Therefore, by forming a second semiconductor layer having large resistance (i.e. the compensation layer having large resistance) on the surface of a first semiconductor layer having lower resistance (i.e. the channel layer having low resistance), a large portion of the voltage drop between the drain electrode metal layer and the source electrode metal layer, i.e. the drain electrode/source electrode voltage drop, is designated to the compensation layer when the transistor is operated. In other words, only a small portion of the drain electrode/source electrode voltage drop is designated to the channel layer. As a result, even after the transistor having the low hot-carrier effect characteristic of the present invention has been operated in a high current environment for a long time, such as in the driver ICs of an OLED display device, the electrons traveling in the channel layer of the transistor can only have limited kinetic energy. Therefore, even though the transistor having the low hot-carrier effect characteristic of the present invention has been operated in a high current environment or a high voltage environment for a long time, the kinetic energies of the charge carriers traveling in its channel layer are still limited, and the probability of the happening of the “hot-carrier effect” on the transistor having the low hot-carrier effect characteristic of the present invention is minimized. Besides, the life time of the transistor having the low hot-carrier effect characteristic of the present invention is longer than the life time of the transistor having the lightly doped drain electrode structure of the prior art operated in a similar operation environment.

The semiconductor structure having a low hot-carrier effect characteristic of the present invention can have any kind of metal layer, preferably the metal layer is made of aluminum, aluminum alloy, molybdenum, molybdenum-tungsten alloy, chromium, copper, nickel, gold, silver or titanium. The first semiconductor layer of the semiconductor structure having a low hot-carrier effect characteristic of the present invention can be formed through any kind of method, preferably the first semiconductor layer is formed through the plasma-enhanced chemical vapor deposition method (PECVD) or the other chemical vapor deposition method (CVD). The second semiconductor layer of the semiconductor structure having a low hot-carrier effect characteristic of the present invention can be formed through any kind of method, preferably the second semiconductor layer is formed through the plasma-enhanced chemical vapor deposition method (PECVD) or the other chemical vapor deposition method (CVD). The second semiconductor layer of the semiconductor structure having a low hot-carrier effect characteristic of the present invention can have the second resistance in any range, preferably the second resistance of the second semiconductor layer is 10² to 10⁹ times the first resistance of the first semiconductor layer, most preferably the second resistance of the second semiconductor layer is 10⁵ times the first resistance of the first semiconductor layer. The semiconductor structure having a low hot-carrier effect characteristic of the present invention can be applied in any kind of IC, preferably the semiconductor structure having a low hot-carrier effect characteristic of the present invention is applied inside a driver IC of an OLED display device.

The transistor having a low hot-carrier effect characteristic of the present invention can have any kind of gate electrode metal layer, preferably the gate electrode metal layer is made of aluminum, aluminum alloy, molybdenum, molybdenum-tungsten alloy, chromium, copper, nickel, gold, silver or titanium. The transistor having a low hot-carrier effect characteristic of the present invention can have any kind of source electrode metal layer, preferably the source electrode metal layer is made of aluminum, aluminum alloy, molybdenum, molybdenum-tungsten alloy, chromium, copper, nickel, gold, silver or titanium. The transistor having a low hot-carrier effect characteristic of the present invention can have any kind of drain electrode metal layer, preferably the drain electrode metal layer is made of aluminum, aluminum alloy, molybdenum, chromium, copper, molybdenum-tungsten alloy, nickel, gold, silver or titanium. The first semiconductor layer of the transistor having a low hot-carrier effect characteristic of the present invention can be formed through any kind of method, preferably the first semiconductor layer is formed through the plasma-enhanced chemical vapor deposition method (PECVD) or the other chemical vapor deposition method (CVD). The transistor having a low hot-carrier effect characteristic of the present invention can be applied in any kind of IC, preferably the transistor of the present invention is applied inside a driver IC of an OLED display device. The second semiconductor layer of the transistor having a low hot-carrier effect characteristic of the present invention can be formed through any kind of method, preferably the second semiconductor layer is formed through the plasma-enhanced chemical vapor deposition method (PECVD) or the other chemical vapor deposition method (CVD). The transistor having a low hot-carrier effect characteristic of the present invention can have any kind of heavily doped semiconductor layer, preferably the heavily doped semiconductor layer is made of amorphous silicon, single-crystal silicon or poly-crystal silicon. The second semiconductor layer of the transistor having a low hot-carrier effect characteristic of the present invention can have the second resistance in any range, preferably the second resistance of the second semiconductor layer is 10² to 10⁹ times the first resistance of the first semiconductor layer, most preferably the second resistance of the second semiconductor layer is 10⁵ times the first resistance of the first semiconductor layer.

Other objects, advantages, and novel features of the invention will become more apparent from the following detailed description when taken in conjunction with the accompanying drawings.

### BRIEF DESCRIPTION OF THE DRAWINGS

FIG. 1A is a schematic diagram of the transistor having the lightly doped drain electrode structure of the prior art.

FIG. 1B is a schematic diagram showing the variation of the on-current regarding the operation time of the transistor having the lightly doped drain electrode structure of the prior art.

FIG. 2 is a schematic diagram of the transistor having the low hot-carrier effect characteristic according to the first preferred embodiment of the present invention.

FIG. 3A and FIG. 3B are schematic diagrams showing the manufacturing processes of the transistor having the low hot-carrier effect characteristic according to the first preferred embodiment of the present invention.

FIG. 4 is a schematic diagram showing the variation of the on-current of the transistor having the low hot-carrier effect characteristic according to the first preferred embodiment of the present invention, regarding the operation time of the transistor.

FIG. 5A is a schematic diagram showing the relation between the gate electrode voltage and the drain electrode current of the transistor having the low hot-carrier effect characteristic according to the first preferred embodiment of the present invention, for different operation times of the transistor.

FIG. 5B is an enlarged diagram showing the portion of FIG. 5A where the gate electrode voltage of the transistor having the low hot-carrier effect characteristic according to the first preferred embodiment of the present invention is within the range from 2 V to 10 V.

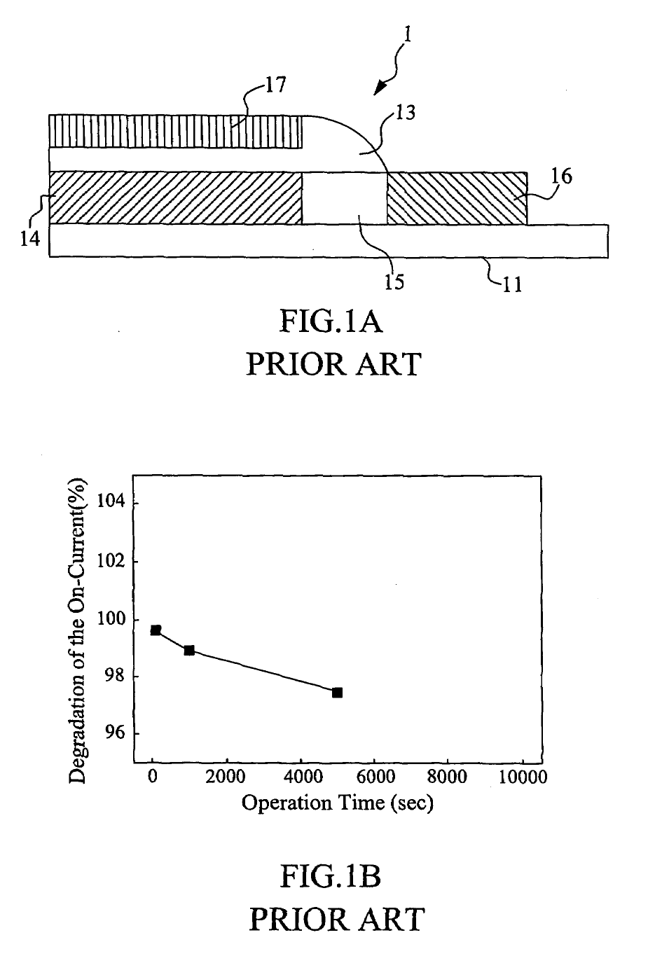

### DETAILED DESCRIPTION OF THE PREFERRED EMBODIMENT

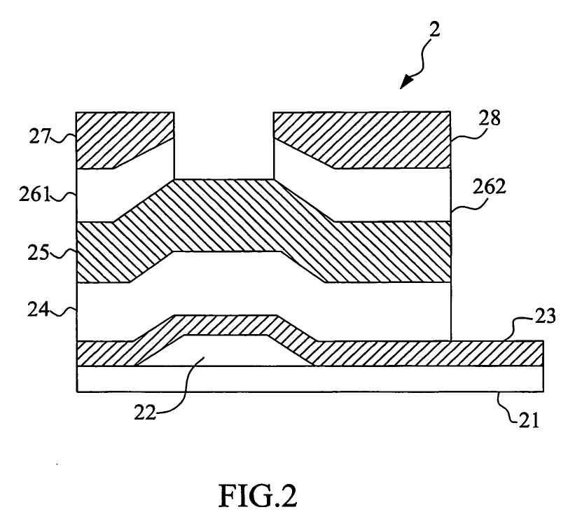

With reference to FIG. 2, which is a schematic diagram of the transistor having the low hot-carrier effect characteristic according to the first preferred embodiment of the present invention, a transistor 2 comprises: a substrate 21, a gate electrode metal layer 22, a gate electrode insulation layer 23, a channel layer 24, a compensation layer 25 having large resistance, a first heavily doped semiconductor layer 261, a second heavily doped semiconductor layer 262, a source electrode metal layer 27, and a drain electrode metal layer 28, wherein the gate electrode metal layer 22, the source electrode metal layer 27, and the drain electrode metal layer 28 are made of aluminum. Besides, the channel layer 24 and the compensation layer 25 formed on the upper surface of the channel layer 24 are formed through the plasma enhanced chemical vapor deposition method (PECVD). Moreover, by doping the impurity with different concentration into these two layers, the resistance of the compensation layer 25 is controlled to be larger than that of the channel layer 24. In general, the resistance of the compensation layer 25 is 10² to 10⁹ times the resistance of the channel layer 24, preferably the resistance of the compensation layer 25 is 10⁵ times the resistance of the channel layer 24. Furthermore, the first heavily doped semiconductor layer 261 and the second heavily doped semiconductor layer 262 are made of amorphous silicon, and the carrier concentration of the heavily doped semiconductor layers range from 10¹⁴ atom/cm³ to 10¹⁹ atom/cm³.

When the transistor 2 having the low hot-carrier effect characteristic according to the first preferred embodiment of the present invention is in its “operation state”, a large portion of the voltage drop between the drain electrode metal layer 28 and the source electrode metal layer 27, i.e. the drain electrode/source electrode voltage drop, is designated to the compensation layer 25 having large resistance. As a result, only a small portion of the drain electrode/source electrode voltage drop is designated to the channel layer 25 locating beneath the compensation layer 25. As a result, even when the transistor 2 having the low hot-carrier effect characteristic according to the first preferred embodiment of the present invention is operated in a high current environment, such as being operated in the driver ICs of an OLED display device, the kinetic energies of the electrons traveling in the channel layer 24 of the transistor 2 are still limited, for the reason that the kinetic energy of an electron traveling in the channel layer 24 is proportional to the voltage drop between the two terminals of the channel layer 24. Hence, even when the transistor 2 having the low hot-carrier effect characteristic according to the first preferred embodiment of the present invention has been operated in a high current environment or a high voltage environment for a long time, the kinetic energies of the charge carriers, i.e. the electrons, traveling in its channel layer are still limited, and the probability of the happening of the “hot-carrier effect” on the transistor having the low hot-carrier effect characteristic according to the first preferred embodiment of the present invention is minimized. As a result, even after being operated in the high current environment or the high voltage environment, the life time of the transistor having the low hot-carrier effect characteristic according to the first preferred embodiment of the present invention is longer than the life time of the transistor having the having the lightly doped drain electrode structure of the prior art operated in a similar operation environment.

Moreover, since in the transistor having the low hot-carrier effect characteristic according to the first preferred embodiment of the present invention, the compensation layer 25 is locating on the upper surface of the channel layer 24 and self-aligned with the channel layer 24 beneath it, the compensation layer 25 does not cover any extra substrate surface. Instead, it just covers at least portions of the upper surface of the channel layer 24. Therefore, comparing with the conventional transistor having the low hot-carrier effect characteristic, such as the transistor having t h e lightly doped drain electrode structure of the prior art, the transistor having the low hot-carrier effect characteristic according to the first preferred embodiment of the present invention only occupies a small area of the substrate surface. Besides, since the manufacturing process of the transistor having the low hot-carrier effect characteristic according to the first preferred embodiment of the present invention does not include any expensive manufacturing process, such as the ion implantation process or the dopant activation annealing process, and the number of the masks required in the whole manufacturing process is also reduced, the manufacturing cost of the transistor having the low hot-carrier effect characteristic according to the first preferred embodiment of the present invention is further lowered than that of the transistor having the lightly doped drain electrode structure of the prior art.

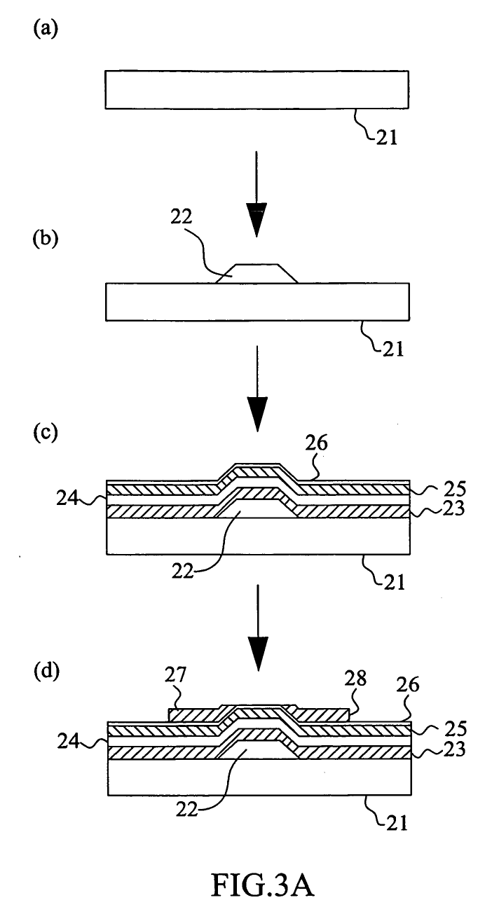

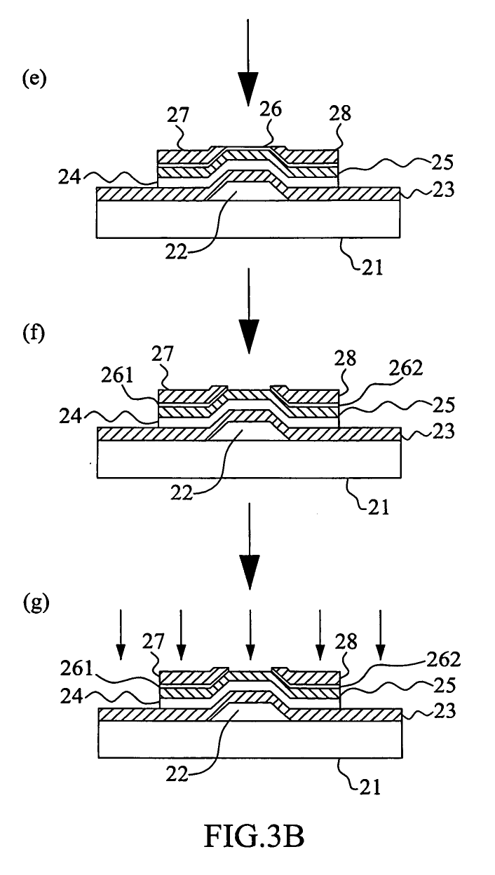

With reference to FIG. 3A and FIG. 3B, the manufacturing process of the transistor having the low hot-carrier effect characteristic according to the first preferred embodiment of the present invention comprises the following steps:

Step (a): providing a glass substrate 21;

Step (b): forming an aluminum layer on the surface of the glass substrate 21 through a sputtering deposition method or a vapor deposition method, defining the pattern of the gate electrode metal layer 22 by a photolithography process, and forming the pattern of the gate electrode metal layer 22 by an etching process;

Step (c): forming a gate electrode insulation layer 23 on the surfaces of the gate electrode metal layer 22 and the glass substrate 21 through the plasma enhanced chemical vapor deposition (PECVD) method; forming a channel layer 24 on the surface of the gate electrode insulation layer 23 through the plasma enhanced chemical vapor deposition (PECVD) method; forming a compensation layer 25 on the surface of the channel layer through the plasma enhanced chemical vapor deposition (PECVD) method with different process parameters than those of the plasma enhanced chemical vapor deposition (PECVD) method forming the channel layer, so as to make the resistance of the compensation layer 25 larger than that of the channel layer 24; forming a heavily doped semiconductor layer 26 on the surface of the compensation layer 25 through the plasma enhanced chemical vapor deposition (PECVD) method;

Step (d): forming an aluminum layer on the surface of the heavily doped semiconductor layer 26 through a sputtering deposition method or a vapor deposition method, defining the pattern of the source electrode metal layer 27 and the drain electrode metal layer 28 by a photolithography process, and forming the pattern of the source electrode metal layer 27 and the drain electrode metal layer 28 by an etching process;

Step (e): defining the pattern of the active area of the transistor by the photolithography process, and forming the pattern of the active area of the transistor by an etching process;

Step (f): removing the heavily doped semiconductor layer 26 between the source electrode metal layer 27 and the drain electrode metal layer 28 by an etching process, so as to form a first heavily doped semiconductor layer 261 and a second heavily doped semiconductor layer 262 on the surface of the compensation layer 25;

Step (g): executing a sintering process in a furnace, so as to improve both the ohmic contact between the first heavily doped semiconductor layer 261 and the source electrode metal layer 27, and the ohmic contact between the second heavily doped semiconductor layer 262 and the drain electrode metal layer 28.

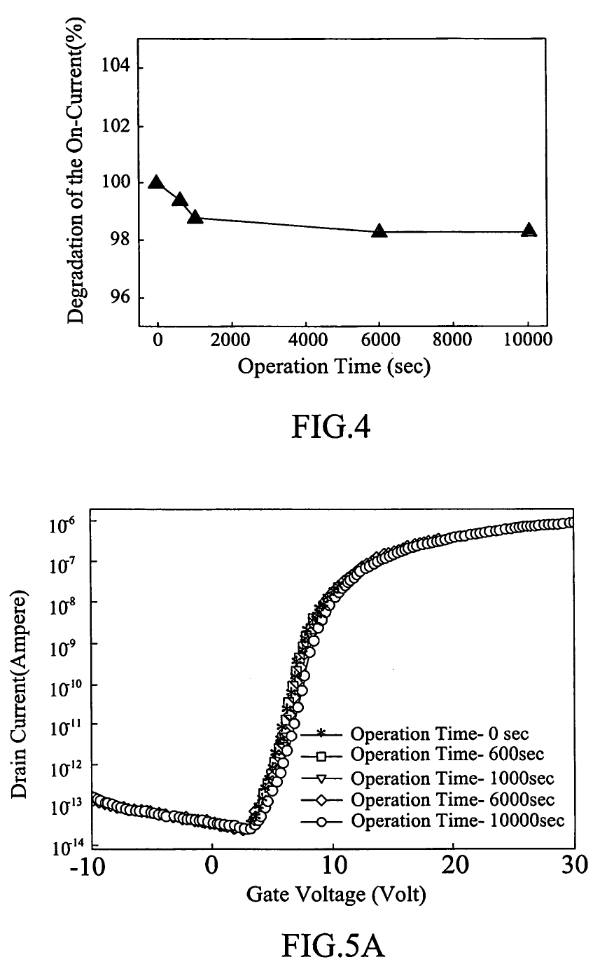

FIG. 4 is a schematic diagram showing the variation of the on-current of the transistor having the low hot-carrier effect characteristic according to the first preferred embodiment of the present invention, regarding the operation time of the transistor. During the operation of the transistor having the low hot-carrier effect characteristic according to the first preferred embodiment of the present invention, its gate electrode/source electrode voltage drop (Vgs) is 20 V, and its drain electrode/source electrode voltage drop (Vds) is 80 V. As shown in FIG. 4, even when being operated in such a severe environment, the on-current of the transistor having the low hot-carrier effect characteristic according to the first preferred embodiment of the present invention can still be maintained at a level which is larger than 98% of its initial value. Especially after the transistor has been operated for over 2000 seconds, the on-current thereof can be maintained steadily at a level which is larger than 98% of its initial value, till the end of the measurement when the transistor has been operated for 10000 seconds. Therefore, the performance parameters of the transistor having the low hot-carrier effect characteristic according to the first preferred embodiment of the present invention are maintained at the levels that are similar to their initial values, even after the transistor has been operated in a severe environment for such a long time (over 10000 seconds). In other words, the transistor having the low hot-carrier effect characteristic according to the first preferred embodiment is advantageous over the transistor having the low doped drain electrode structure of the prior art in the minimization of the detrimental influence of the happening of the hot-carrier effect on the performance thereof.

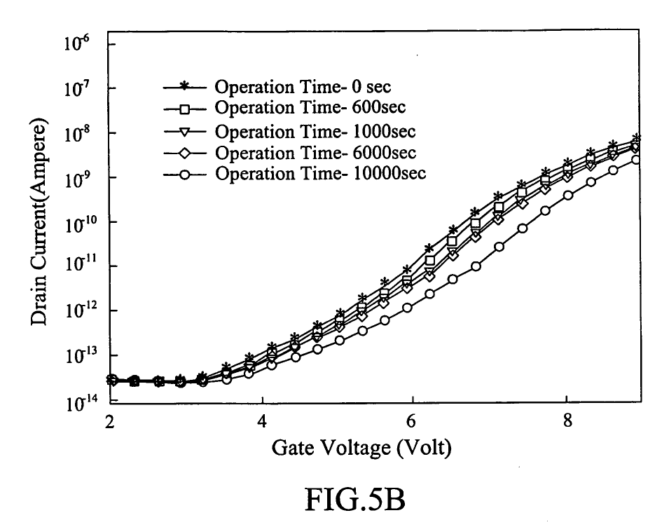

FIG. 5A is a schematic diagram showing the relation between the gate electrode voltage and the drain electrode current of the transistor having the low hot-carrier effect characteristic according to the first preferred embodiment of the present invention, for different operation times of the transistor, wherein the gate electrode-source electrode voltage drop (V g s ) of the transistor is 20 V, and the drain electrode/source electrode voltage drop (Vds) of the transistor is 80 V. Besides, when the transistor having the low hot-carrier effect characteristic according to the first preferred embodiment of the present invention is measured for its performance parameters, the gate electrode/source electrode voltage drop (Vgs) of the transistor is reduced to 5.1 V. As shown in FIG. 5A, in different operation times of the transistor, the relations between its gate electrode voltage and its drain electrode current of the transistor are similar. This is another item of evidence proving that the performance parameters, such as the relation between its gate electrode voltage and its drain electrode current, of the transistor having the low hot-carrier effect characteristic according to the first preferred embodiment of the present invention is not influenced by the happening of the hot-carrier effect, even after the transistor has been operated for such a long time.

FIG. 5B is an enlarged diagram showing the portion of FIG. 5A where the gate electrode voltage of the transistor having the low hot-carrier effect characteristic according to the first preferred embodiment of the present invention is within the range from 2 V to 10 V. As shown in FIG. 5B, the threshold voltage (VTH) of the transistor according to the first preferred embodiment of the present invention does not increase significantly, even though the transistor has been operated for a long time. In general, when the hot-carrier effect happens in a transistor, the charge carriers traveling in the channel layer of the transistor will inject into the gate electrode insulation layer and/or the interface between the gate electrode insulation layer and the channel layer, resulting in the increase of the threshold voltage of the transistor and the deterioration of the performance of the transistor. As a result, even after the transistor according to the first preferred embodiment of the present invention has been operated in such a severe environment (Vgs=20V, Vds=80V) for such a long time (over 10000 seconds), the transistor according to the first preferred embodiment of the present invention can still minimize the detrimental influence of the happening of the hot-carrier effect on its performance and so maintain its threshold voltage at a level which is similar to its initial value. For this advantageous characteristic, the transistor having the low hot-carrier effect characteristic is suitable for the application having a large-current environment, such as the driver ICs of an OLED display device.

The schematic diagram of the transistor having the low hot-carrier effect characteristic according to the second preferred embodiment of the present invention is similar to the one shown in FIG. 2. That is, the structure of the transistor having the low hot-carrier effect characteristic according to the second preferred embodiment of the present invention is similar to the structure of the transistor having the low hot-carrier effect characteristic according to the first preferred embodiment of the present invention, except for the difference on the material of the gate electrode metal layer 22, the source electrode metal layer 27, and the drain electrode metal layer 28. In the second preferred embodiment of the present invention, the gate electrode metal layer 22, the source electrode metal layer 27, and the drain electrode metal layer 28 are all made of copper.

As described above, since the structure of the transistors according to these two preferred embodiments of the present invention are similar, so even after the transistor having the low hot-carrier effect characteristic according to the second preferred embodiment of the present invention has been operated in a high current environment or a high voltage environment for a long time, the kinetic energies of the charge carriers traveling in its channel layer are still limited, and the probability of the happening of the “hot-carrier effect” on the transistor is also minimized. Therefore, even after being operated in a high current environment or a high voltage environment, the life time of the transistor having the low hot-carrier effect characteristic according to the second preferred embodiment of the present invention is still longer than the life time of the transistor having the lightly doped drain electrode structure of the prior art operated in a similar operation environment.

Moreover, since in the transistor of the present preferred embodiment, the compensation layer 25 having large resistance is locating on the upper surface of the channel layer 24, and self-aligned with the channel layer 24 beneath it, the compensation layer 25 does not cover any extra substrate surface. Instead, it just covers at least portions of the upper surface of the channel layer 24. Therefore, comparing with the conventional transistor having the low hot-carrier effect characteristic, such as the transistor having the lightly doped drain electrode structure of the prior art, the transistor having the low hot-carrier effect characteristic according to the second preferred embodiment of the present invention only occupies a smaller area of the substrate surface. Besides, since the manufacturing process of the transistor having the low hot-carrier effect characteristic according to the second preferred embodiment of the present invention does not include any expensive manufacturing process, such as the ion implantation process or the dopant activation annealing process, and the number of the masks required in the whole manufacturing process is also reduced, the manufacturing cost of the transistor having the low hot-carrier effect characteristic according to the second preferred embodiment of the present invention is further lowered relative to the transistor having the lightly doped drain electrode structure of the prior art.

With reference to FIG. 3A and FIG. 3B again, the manufacturing process of the transistor having the low hot-carrier effect characteristic according to the second preferred embodiment of the present invention comprises the following steps:

Step (a): providing a glass substrate 21;

Step (b): forming a copper layer on the surface of the glass substrate 21 through a sputtering deposition method or a vapor deposition method, defining the pattern of the gate electrode metal layer 22 by a photolithography process, and forming the pattern of the gate electrode metal layer 22 by an etching process;

Step (c): forming a gate electrode insulation layer 23 on the surfaces of the gate electrode metal layer 22 and the glass substrate 21 through the plasma enhanced chemical vapor deposition (PECVD) method; forming a channel layer 24 on the surface of the gate electrode insulation layer 23 through the plasma enhanced chemical vapor deposition (PECVD) method; forming a compensation layer 25 on the surface of the channel layer through the plasma enhanced chemical vapor deposition (PECVD) method with different process parameters than those of the plasma enhanced chemical vapor deposition (PECVD) method forming the channel layer, so as to make the resistance of the compensation layer 25 larger than that of the channel layer 24; forming a heavily doped semiconductor layer 26 on the surface of the compensation layer 25 through the plasma enhanced chemical vapor deposition (PECVD) method;

Step (d): forming a copper layer on the surface of the heavily doped semiconductor layer 26 through a sputtering deposition method or a vapor deposition method, defining the pattern of the source electrode metal layer 27 and the drain electrode metal layer 28 by a photolithography process, and forming the pattern of the source electrode metal layer 27 and the drain electrode metal layer 28 by an etching process;

Step (e): defining the pattern of the active area of the transistor by a photolithography process, and forming the pattern of the active area of the transistor by an etching process;

Step (f): removing the heavily doped semiconductor layer 26 between the source electrode metal layer 27 and the drain electrode metal layer 28 by an etching process, so as to form a first heavily doped semiconductor layer 261 and a second heavily doped semiconductor layer 262 on the surface of the compensation layer 25;

Step (g): executing a sintering process in a furnace, so as to improve both the ohmic contact between the first heavily doped semiconductor layer 261 and the source electrode metal layer 27, and the ohmic contact between the second heavily doped semiconductor layer 262 and the drain electrode metal layer 28.

The schematic diagram of the transistor having the low hot-carrier effect characteristic according to the third preferred embodiment of the present invention is similar to the one shown in FIG. 2. That is, the structure of the transistor having the low hot-carrier effect characteristic according to the third preferred embodiment of the present invention is similar to the structure of the transistor having the low hot-carrier effect characteristic according to the first preferred embodiment of the present invention, except for the difference on the material of the gate electrode metal layer 22, the source electrode metal layer 27, and the drain electrode metal layer 28. In the third preferred embodiment of the present invention, the gate electrode metal layer 22, the source electrode metal layer 27, and the drain electrode metal layer 28 are all made of molybdenum-tungsten alloy, not aluminum.

As described above, since the structure of the transistor having the low hot-carrier effect characteristic according to the third preferred embodiment of the present invention is similar to that of the transistor having the low hot-carrier effect characteristic according to the first preferred embodiment of the present invention, so even after this transistor has been operated in a high current environment or a high voltage environment for a long time, the kinetic energies of the charge carriers traveling in its channel layer are still limited, and the probability of the happening of the “hot-carrier effect” on the transistor * is also minimized. Therefore, even after being operated in a high current environment or a high voltage environment, the life time of the transistor having the low hot-carrier effect characteristic according to the third preferred embodiment of the present invention is still longer than the life time of the transistor having the lightly doped drain electrode structure of the prior art operated in a similar operation environment.

Moreover, since in the transistor of the present preferred embodiment of the present invention, the compensation layer 25 having large resistance is locating on the upper surface of the channel layer 24, and self-aligned with the channel layer 24 beneath it, the compensation layer 25 does not cover any extra substrate surface. Instead, it just covers at least portions of the upper surface of the channel layer 24. Therefore, comparing with the conventional transistor having the low hot-carrier effect characteristic, such as the transistor having the lightly doped drain electrode structure of the prior art, the transistor having the low hot-carrier effect characteristic according to the third preferred embodiment of the present invention only occupies a small area of the substrate surface. Besides, since the manufacturing process of the transistor having the low hot-carrier effect characteristic according to the third preferred embodiment of the present invention does not include any expensive manufacturing process, such as the ion implantation process or the dopant activation annealing process, and the number of the masks in the whole manufacturing process is also reduced, the manufacturing cost of the transistor having the low hot-carrier effect characteristic according to the third preferred embodiment of the present invention is further lowered relative to that of the transistor having the lightly doped drain electrode structure of the prior art.

With reference to FIG. 3A and FIG. 3B once again, the manufacturing process of the transistor having the low hot-carrier effect characteristic according to the third preferred embodiment of the present invention comprises the following steps:

Step (a): providing a glass substrate 21;

Step (b): forming a molybdenum-tungsten alloy layer on the surface of the glass substrate 21 through a sputtering deposition method or a vapor deposition method, defining the pattern of the gate electrode metal layer 22 by a photolithography process, and forming the pattern of the gate electrode metal layer 22 by an etching process;

Step (c): forming a gate electrode insulation layer 23 on the surfaces of the gate electrode metal layer 22 and the glass substrate 21 through the plasma enhanced chemical vapor deposition (PECVD) method; forming a channel layer 24 on the surface of the gate electrode insulation layer 23 through the plasma enhanced chemical vapor deposition (PECVD) method; forming a compensation layer 25 on the surface of the channel layer through the plasma enhanced chemical vapor deposition (PECVD) method with different process parameters than those of the plasma enhanced chemical vapor deposition (PECVD) method forming the channel layer, so as to make the resistance of the compensation layer 25 larger than that of the channel layer 24; forming a heavily doped semiconductor layer 26 on the surface of the compensation layer 25 through the plasma enhanced chemical vapor deposition (PECVD) method;

Step (d): forming a molybdenum-tungsten alloy layer on the surface of the heavily doped semiconductor layer 26 through a sputtering deposition method or a vapor deposition method, defining the pattern of the source electrode metal layer 27 and the drain electrode metal layer 28 by a photolithography process, and forming the pattern of the source electrode metal layer 27 and the drain electrode metal layer 28 by an etching process;

Step (e): defining the pattern of the active area of the transistor by a photolithography process, and forming the pattern of the active area of the transistor by an etching process;

Step (f): removing the heavily doped semiconductor layer 26 between the source electrode metal layer 27 and the drain electrode metal layer 28 by the etching process, so as to form a first heavily doped semiconductor layer 261 and a second heavily doped semiconductor layer 262 on the surface of the compensation layer 25;

Step (g): executing a sintering process in a furnace, so as to improve both the ohmic contact between the first heavily doped semiconductor layer 261 and the source electrode metal layer 27, and the ohmic contact between the second heavily doped semiconductor layer 262 and the drain electrode metal layer 28.

In summary, by forming a second semiconductor layer having a large resistance (i.e. the compensation layer having a large resistance) on the surface of a first semiconductor layer having lower resistance (i.e. the channel layer having low resistance), a large portion of the voltage drop between the drain electrode metal layer and the source electrode metal layer, i.e. the drain electrode/source electrode voltage drop, is designated to the compensation layer when the transistor is operated. In other words, only a small portion of the drain electrode/source electrode voltage drop is designated to the channel layer. As a result, even after the transistor having the low hot-carrier effect characteristic of the present invention has been operated in a high current environment for a long time, such as in the driver ICs of an OLED display device, the electrons traveling in the channel layer of the transistor can only have limited kinetic energy. Therefore, even though the transistor having the low hot-carrier effect characteristic of the present invention has been operated in a high current environment or a high voltage environment for a long time, the kinetic energies of the charge carriers traveling in its channel layer are still limited, and the probability of the happening of the “hot-carrier effect” on the transistor having the low hot-carrier effect characteristic of the present invention is minimized. Besides, the life time of the transistor having the low hot-carrier effect characteristic of the present invention is longer than the life time of the transistor having the lightly doped drain electrode structure of the prior art operated in a similar operation environment.

Although the present invention has been explained in relation to its preferred embodiment, it is to be understood that many other possible modifications and variations can be made without departing from the scope of the invention as hereinafter claimed.

What is claimed is:

1. A semiconductor structure having a low hot-carrier effect characteristic, comprising:
a substrate;
a metal layer formed on at least part of the surface of the substrate;
an insulation layer formed on at least part of the surface of the substrate and covering the surface of the metal layer;
a first semiconductor layer having a first resistance covering at least part of the surface of the insulation layer; and
a second semiconductor layer having a second resistance and covering at least part of the surface of the first semiconductor layer;
wherein the second resistance of the second semiconductor layer is larger than the first resistance of the first semiconductor layer.

2. The semiconductor structure as claimed in claim 1, wherein the metal layer is made of aluminum.

3. The semiconductor structure as claimed in claim 1, wherein the first semiconductor layer is formed through the plasma-enhanced chemical vapor deposition method.

4. The semiconductor structure as claimed in claim 1, wherein the second semiconductor layer is formed through the plasma-enhanced chemical vapor deposition method.

5. The semiconductor structure as claimed in claim 1, wherein the semiconductor structure is applied inside a driver IC of an OLED display device.

6. The semiconductor structure as claimed in claim 1, wherein the second resistance of the second semiconductor layer is 102 to 109 times the first resistance of the first semiconductor layer.

7. The semiconductor structure as claimed in claim 1, wherein the second semiconductor layer covers an upper-sided surface of the first semiconductor layer.

8. A transistor having a low hot-carrier effect characteristic, comprising:
a substrate;
a gate electrode metal layer formed on at least part of the surface of the substrate;
an insulation layer formed on at least part of the surface of the substrate and covering the surface of the gate electrode metal layer;
a first semiconductor layer having a first resistance and covering at least part of the surface of the insulation layer;
a second semiconductor layer having a second resistance and covering at least part of the surface of the first semiconductor layer;
a heavily doped semiconductor layer having a first upper surface and a second upper surface and covering at least part of the surface of the second semiconductor layer;
a source electrode metal layer formed on the first upper surface of the heavily doped semiconductor layer; and
a drain electrode metal layer formed on the second upper surface of the heavily doped semiconductor layer;
wherein the second resistance of the second semiconductor layer is larger than the first resistance of the first semiconductor layer.

9. The transistor as claimed in claim 8, wherein the gate electrode metal layer is made of aluminum.

10. The transistor as claimed in claim 8, wherein the source electrode metal layer is made of aluminum.

11. The transistor as claimed in claim 8, wherein the drain electrode metal layer is made of aluminum.

12. The transistor as claimed in claim 8, wherein the gate electrode metal layer is made of copper.

13. The transistor as claimed in claim 8, wherein the source electrode metal layer is made of copper.

14. The transistor as claimed in claim 8, wherein the drain electrode metal layer is made of copper.

15. The transistor as claimed in claim 8, wherein the gate electrode metal layer is made of molybdenum-tungsten alloy.

16. The transistor as claimed in claim 8, wherein the source electrode metal layer is made of molybdenum-tungsten alloy.

17. The transistor as claimed in claim 8, wherein the drain electrode metal layer is made of molybdenum-tungsten alloy.

18. The transistor as claimed in claim 8, wherein the first semiconductor layer is formed through the plasma-enhanced chemical vapor deposition method.

19. The transistor as claimed in claim 8, wherein the first semiconductor layer is a channel layer.

20. The transistor as claimed in claim 8, wherein the second semiconductor layer is formed through the plasma-enhanced chemical vapor deposition method.

21. The transistor as claimed in claim 8, wherein the second semiconductor layer is a compensation layer having large-resistance.

22. The transistor as claimed in claim 8, wherein the transistor is applied inside a driver IC of an OLED display device.

23. The transistor as claimed in claim 8, wherein the carrier concentration of the heavily doped semiconductor layer ranges from 10¹⁴ atom/cm³ to 10¹⁹ atom/cm³.

24. The transistor as claimed in claim 8, wherein the heavily doped semiconductor layer is made of amorphous silicon.

25. The transistor as claimed in claim 8, wherein the second resistance of the second semiconductor layer is 10² to 10⁹ times the first resistance of the first semiconductor layer.

26. The transistor as claimed in claim 8, wherein the second semiconductor layer covers an upper-sided surface of the first semiconductor layer.
